(19) United States
(12) Patent Application Publication
(10) Pub. No.: US 2011/0148441 A1
(43) Pub. Date: Jun. 23, 2011

(54) Quantum computing device and using method thereof

(75) Inventors: Tsuyoshi Yamamoto, Tokyo (JP); Jaw-Shen Tsai, Tokyo (JP)

(73) Assignee: NEC CORPORATION, Tokyo (JP)

(21) Appl. No.: 10/539,753

(22) PCT Filed: Dec. 22, 2003
(86) PCT No.: PCT/JP2003/016475

§ 371 Date: Jun. 20, 2005

(30) Foreign Application Priority Data
Dec. 20, 2002 (JP) 2002-370135

(51) Int. Cl. H01L 47/00; G01R 27/26; B82Y 10/00

(52) U.S. Cl. 324/686; 257/36; 977/933

(57) ABSTRACT

With a simple circuit configuration which does not conduct high frequency signal processing, a quantum computing device, a quantum bit readout processing unit of the quantum computing device, and a quantum bit readout processing method are provided. By controlling a quantum bit structure, which is formed with a counter electrode coupling with a quantum box electrode through a first tunnel barrier, with a gate voltage, a Cooper-pair extracted from the quantum box electrode after computation is accumulated in a trap electrode coupling with the quantum bit structure by sandwiching a second tunnel barrier. By coupling the trap electrode and an island electrode of a readout single electron transistor through a static capacitance, a change of electric charge in the trap electrode is read out as a direct current value of the single electron transistor.

### FIELD OF THE INVENTION

The present invention relates to a quantum computing device composed of a Josephson coupling system for a quantum computer and a using method of the element, and, more particularly to a readout processing unit of a quantum bit of the quantum computing device and a readout processing method of the quantum bit of the quantum computing device.

### BACKGROUND OF THE INVENTION

All of patents, patent applications, patent publications, scientific articles and the like, which will hereinafter be cited or identified in the present application, will hereby be incorporated by references in their entirety in order to describe more fully the state of the art, to which the present invention pertains.

A use of a superconducting quantum computing device for the quantum computer has been known. An example of a conventional superconducting quantum computing device has been disclosed in paragraphs [0013], [0015] and FIG. 1 of Japanese Laid-Open Patent Publication No. 2000-277723.

FIG. 1 is a circuit diagram showing an example of a configuration of the conventional superconducting quantum computing device. The conventional superconducting quantum computing device comprises superconducting box electrode 205, counter electrode 204 coupled with a first side of the superconducting box electrode 205 through a first tunnel barrier 207, readout electrode 203 coupled with a second side, which is an opposite side of the first side, of the superconducting box electrode 205 through a second tunnel bather 206, and gate electrode 201 coupled with a third side, which is different from the first side and the second side, of superconducting box electrode 205 through gate capacitance 202.

A number of excess Cooper-pair in superconducting box electrode 205 is limited to 0 (zero) or 1 (one) by charging effect. And, these two quantum states are coherently coupled by tunneling of the Cooper-pair between counter electrode 204 through the first tunnel barrier 207 and superconducting box electrode 205.

A gate voltage applied to gate electrode 201 operates on superconducting box electrode 205 through gate capacitance 202, thereby conducting a computation for the quantum bit.

In addition, readout electrode 203 is disposed on superconducting box electrode 205 through the second tunnel barrier 206.

The second tunnel barrier 206 is formed thicker, that is, for sufficiently reducing a tunneling probability, than the first tunnel barrier 207 so as to maintain coherence of the Cooper-pair as long as possible.

Readout electrode 203 is positively biased by a voltage source. If an excess Cooper-pair exists in superconducting box electrode 205, it is extracted through two quasi-particles tunneling, thereby giving a certain current.

On the other hand, if there is no excess Cooper-pair, nothing happens. Therefore, by measuring a current flowing the above junction, a distinction of the two states, that is, readout of the quantum state can be achieved.

Since a detection of a current caused by relaxation of a single Cooper-pair is difficult from view point of measurement accuracy, a detectable current has been obtained by averaging many repeated results of the same computation.

In addition, there is another example of a conventional technology of the readout for a single trial by using a high frequency single electron transistor. The conventional technology has been disclosed in Science (U.S.), 1998 May 22, vol. 280, p. 1238-1242.

However, a conventional computing element conducts a plurality of trial measurements, and a final result is obtained by calculating the average of them. In this case, information on correlation of quantum state can not be obtained.

In addition, since a high frequency signal is used in the conventional technology using the high frequency single electron transistor, a configuration of the quantum computing circuit becomes complex in total.

The present invention has been developed under the above-described technology background. Therefore, it provides a quantum computing device which is not needed to conduct a plurality of trail measurements, and which also achieves a simple configuration of the quantum computing circuit without using a high frequency signal.

### DISCLOSURE OF THE INVENTION

It is therefore an object of the present invention to provide a quantum computing device which is able to read out a quantum state with a single trial with a simple circuit configuration which does not conduct a high frequency signal processing.

It is another object of the present invention to provide a quantum bit readout processing unit of the quantum computing device, which is able to read out the quantum state with a single trial, with a simple circuit configuration which does not conduct a high frequency signal processing.

It is a further object of the present invention to provide a method for using the quantum computing device, which is able to read out the quantum state with a single trial, with a simple circuit configuration which does not conduct a high frequency signal processing.

It is a still further object of the present invention to provide a quantum bit readout processing method of the quantum computing device, which is able to read out the quantum state with a single trial, with a simple circuit configuration which does not conduct a high frequency signal processing.

A quantum computing device according to a first aspect of the present invention comprises a quantum bit structure coupling a quantum box electrode and a counter electrode by sandwiching a first tunnel barrier; a first gate electrode coupling with the quantum box electrode through a static capacitance; a trap electrode coupling with the quantum box electrode through a second tunnel barrier; and a single electron transistor, wherein the single electron transistor, further comprising a source electrode, drain electrode, an island electrode, and a second gate electrode coupling with the island electrode, wherein the trap electrode and the island electrode of the single electron transistor being coupled through a readout capacitance.

The quantum box electrode, the counter electrode, and the trap electrode may be composed of a superconducting material.

It is favorable that a carrier relaxation time through the second tunnel barrier is longer than a coherent vibration period through the first tunnel barrier.

The carrier relaxation time through the second tunnel barrier may be between 5 times to 1000 times of the coherent vibration period through the first tunnel barrier.

It is favorable that the first tunnel barrier is consist of a first insulating film and the second tunnel barrier is consist of a second insulating film, wherein a thickness of the second insulating film being thicker than a thickness of the first insulating film.

The thickness of the second insulating film may be between 1 times to 3 times of the thickness of the first insulating film.

The island electrode may be coupled with the source electrode through a third tunnel barrier, and may be coupled with the drain electrode through a fourth tunnel barrier.

The quantum computing device may be configured such that, by applying a negative bias voltage to the counter electrode, thereby extracting an excess Cooper-pair existing in the superconducting box electrode to the trap electrode when the negative bias is applied and accumulating the excess Cooper-pair in the trap electrode, a change of current value flowing in the single electron transistor before and after the extraction of the excess Cooper-pair is measured.

The quantum computing device may be configured such that, by applying a positive bias voltage to the trap electrode, thereby extracting an excess Cooper-pair existing in the superconducting box electrode to the trap electrode when the positive bias is applied and accumulating the excess Cooper-pair in the trap electrode, a change of current value flowing in the single electron transistor before and after the extraction of the excess Cooper-pair is measured.

A quantum bit readout processing unit of a quantum computing device according to a second aspect of the present invention comprises a single electron transistor comprising a source electrode, a drain electrode, an island electrode, and a gate electrode coupling with the island electrode through a gate capacitance; and a trap electrode coupling with the island electrode through a readout capacitance as well as coupling with a quantum box electrode of the quantum computing device, wherein the quantum bit readout processing unit being configured so that a change of current value flowing in the single electron transistor is measured before and after extraction of an excess Cooper-pair existing in the quantum box electrode to the trap electrode when a bias voltage is applied to the quantum computing device.

The quantum computing device may comprise a quantum bit structure coupling the quantum box electrode and a counter electrode through a first tunnel bather; a gate electrode coupling with the quantum box electrode through a static capacitance; and the trap electrode coupling with the quantum box electrode through a second tunnel barrier.

The bias voltage to be applied to the quantum computing device may be a negatively biased voltage applied to the counter electrode.

The bias voltage to be applied to the quantum computing device may be a positively biased voltage applied to the trap electrode.

The quantum box electrode, the counter electrode, and the trap electrode may be composed of a superconducting material.

It is favorable that a carrier relaxation time through the second tunnel barrier is longer than a coherent vibration period through the first tunnel barrier.

The carrier relaxation time through the second tunnel barrier may be between 5 times to 1000 times of the coherent vibration period through the first tunnel barrier.

It is favorable that the first tunnel barrier is consist of a first insulating film and the second tunnel barrier is consist of a second insulating film, wherein a thickness of the second insulating film being thicker than a thickness of the first insulating film.

The thickness of the second insulating film may be between 1 times to 3 times of the thickness of the first insulating film.

The island electrode may be coupled with the source electrode through a third tunnel barrier, and may be coupled with the drain electrode through a fourth tunnel barrier.

A quantum bit readout method of a quantum computing device according to a third aspect of the present invention comprises steps of extracting an excess Cooper-pair existing in the quantum box electrode to a trap electrode of the quantum computing device when a bias voltage is applied to the quantum computing device; and measuring a change of a current value flowing in a single electron transistor which includes an island electrode coupling with the trap electrode through a readout capacitance before and after the extracting of the excess Cooper-pair.

The bias voltage to be applied to the quantum computing device may be a negatively biased voltage applied to a counter electrode of the quantum computing device.

The bias voltage to be applied to the quantum computing device may be a positively biased voltage applied to the trap electrode.

In the present invention, the readout capacitance which couples the trap electrode and the island electrode comprises all elements configuring a capacitance in the equivalent circuit. Therefore, a configuration of readout capacitance includes a capacitance having a configuration where the trap electrode and the island electrode are spatially separated without electrical conduction. A typical example of this capacitance configuration includes a static capacitance which couples the trap electrode and the island electrode through vacuum or an insulating material, but not limited to these.

A typical example of the readout capacitance configuration other than the above includes a potential barrier which is not intended to flow a tunnel current, that is, a configuration coupling the trap electrode and the island electrode through a tunnel barrier. It should be noted that a thickness of the potential barrier must be sufficient for not to flow the tunnel current, or hard to flow the current.

Therefore, although the tunnel barrier which separates the trap electrode and the island electrode may be composed of an insulating material forming a normal potential barrier, the function is not to flow a current, but provides a capacitance in the equivalent circuit which couples the trap electrode and the island electrode.

If a thickness of the tunnel barrier between the trap electrode and the island electrode is increased, the tunnel current between the both electrodes can be suppressed sufficiently. However, a sensitivity of the single electron transistor is decreased. On the other hand, if the thickness of the tunnel barrier between the trap electrode and the island electrode is decreased, the sensitivity of the single electron transistor is increased, but becomes difficult to suppress the tunnel current between the both electrodes. Therefore, a design of the readout capacitance which couples the trap electrode and the island electrode must be conducted by considering suppression of the tunnel current between the trap electrode and the island electrode, and securement of high sensitivity of the single electron transistor.

In addition, the single electron transistor is divided into a type of high frequency single electron transistor (RF-SET) which uses a high frequency, and a type of single electron transistor (SET) which does not use a high frequency. In the present invention, it is favorable to use a single electron transistor which does not use a high frequency from the following point of view.

If an island electrode is coupled with a quantum box electrode through a capacitance, a quantum bit state of electron Cooper-pair which is generated in the quantum box electrode and has a very short life time must be observed very quickly before the annihilation of the electron Cooper-pair. Then, the readout single electron transistor must be configured with a high frequency single electron transistor. However, a peripheral circuitry for operating the high frequency single electron transistor with a high frequency becomes very complex, thereby resulting in not preferable.

On the other hand, when an island electrode of a single electron transistor is coupled with a trap electrode through a capacitance, the island electrode of the single electron transistor is coupled with the trap electrode, which is coupled with a quantum box electrode through a tunnel barrier, through a readout capacitance, thereby accumulating an excess Cooper-pair in the trap electrode, and a change of electric charge accumulated in the trap electrode, that is, a change of the number of excess Cooper-pair is read out as a direct current value of the readout single electron transistor. In this case, the readout single electron transistor is not necessary to be configured with a high frequency single electron transistor. That is, since it is not needed to operate a readout single electron transistor with high frequency, the peripheral circuitry can be simplified.

Therefore, a trap electrode coupling with a quantum box electrode through a tunnel barrier, and a single electron transistor which has an island electrode coupling with the trap electrode through a readout capacitance are essential configuration elements for a quantum computing device according to the present invention.

That is, it is configured such that, by applying a bias voltage between a counter electrode and a trap electrode, thereby extracting an excess Cooper-pair existing in a quantum box electrode to the trap electrode when the bias is applied, a change of current value flowing in the single electron transistor before and after the extraction of the excess Cooper-pair is measured.

With this configuration, the excess Cooper-pair existing in the quantum box electrode after quantum computation is accumulated in the trap electrode, thereby a change of electronic charge accumulated in the trap electrode, that is, a change of the number of excess Cooper-pair can be to read as a direct current value of the readout single electron transistor. Therefore, since fast readout of a signal is not necessary, use of a high frequency single electron transistor is not needed. Accordingly, since a high frequency control circuit for operating a single electron transistor with high frequency is not necessary, a circuit configuration of a peripheral circuitry can be simplified.

In addition, by using a single electron transistor as a high sensitive electric charge counter, an observation of quantum bit state becomes possible with a single trial.

Therefore, the quantum computing device according to the present invention is quite different in the configuration and the effect from a quantum computing device which merely directly couples a high frequency single electron transistor with a quantum box electrode of quantum bit structure.

### BRIEF DESCRIPTION OF THE DRAWINGS

FIG. 1 is a schematic circuit diagram showing a superconducting quantum computing device according to a conventional technology and a readout circuit thereof.

FIG. 2 is a schematic circuit diagram showing a configuration of a quantum computing device according to one of the embodiment of the present invention.

FIG. 3 is a schematic view explaining a method of readout of a quantum bit according to one of the embodiment of the present invention.

FIG. 4 is a plane view showing a quantum computing device according to one of the embodiment of the present invention.

FIG. 5A and FIG. 5B are schematic views showing an example of fabrication process of a quantum computing device according to one of the embodiment of the present invention.

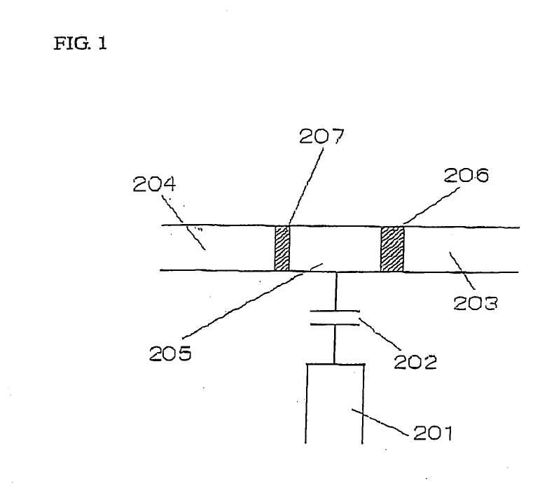

### PREFERRED EMBODIMENTS OF THE PRESENT INVENTION

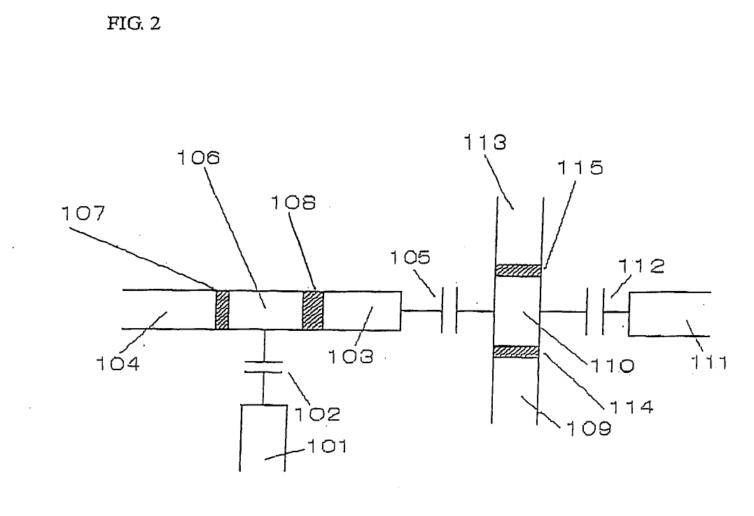

Next, a configuration of embodiment of the present invention will be explained in detail by referring to figures. FIG. 2 is a schematic circuit diagram showing a configuration of a quantum computing device according to one of the embodiment of the present invention. The quantum computing device includes a quantum bit computation processing unit for conducting a computation of the quantum bit and a readout processing unit for processing a readout of the quantum hit of the quantum bit computation processing unit.

The quantum bit computation processing unit includes a quantum bit structure, in which superconducting box electrode 106 as a quantum box electrode and counter electrode 104 are coupled by sandwiching a first tunnel barrier 107, and a first gate electrode 101 which is coupled with the above superconducting box electrode 106 through a first gate capacitance 102.

The above-described readout processing unit includes trap electrode 103 coupled with the above superconducting box electrode 106 through a second tunnel barrier 108, and a single electron transistor coupled with trap electrode 103 through readout capacitance 105.

The single electron transistor includes island electrode 110 coupled with trap electrode 103 through readout capacitance 105, source electrode 109 coupled with island electrode 110 through a third tunnel barrier 114, drain electrode 113 coupled with island electrode 110 through a fourth tunnel barrier 115, and a second gate electrode 111 coupled with the island electrode 110 through a second gate capacitance 112.

Superconducting box electrode 106, counter electrode 104, and trap electrode 103 may be composed of a superconducting substance which becomes to be superconducting state at low temperature. Counter electrode 104 operates as a source electrode. The first gate electrode 101 may be composed of a superconducting substance or a normal conducting substance. The second tunnel barrier 108 which couples trap electrode 103 and superconducting box electrode 106 is formed thinner than the first tunnel barrier 107 which couples counter electrode 104 and superconducting box electrode 106.

Source electrode 109 of the readout single electron transistor, island electrode 110, drain electrode 113, and the second gate electrode 111 may be composed of a superconducting substance, or a normal conducting substance.

Readout capacitance 105 includes all elements configuring a capacitance in the equivalent circuit. Therefore, a configuration of readout capacitance includes a capacitance having a configuration where the trap electrode and the island electrode are spatially separated without electrical conduction. A typical example of this configuration of the capacitance includes a static capacitance which couples trap electrode 103 and island electrode 110 through vacuum or an insulating material, but not limited to these.

A typical example of a configuration of readout capacitance 105 other than the above includes a potential barrier which is not intended to flow a tunnel current, that is, a configuration which couples trap electrode 103 and island electrode 110 through a tunnel barrier. It should be noted that a thickness of the potential barrier must be sufficient for not to flow the tunnel current, or hard to flow the current.

Therefore, although the tunnel barrier separating trap electrode 103 and island electrode 110 may be composed of an insulating material forming a normal potential barrier, the function is not to flow a current, but provides a capacitance in the equivalent circuit which couples trap electrode 103 and island electrode 110.

If a thickness of the tunnel barrier between trap electrode 103 and island electrode 110 is increased, a tunnel current between the electrodes can be suppressed sufficiently. However, a sensitivity of the single electron transistor is decreased. On the other hand, if the thickness of the tunnel barrier between trap electrode 103 and island electrode 110 is decreased, the sensitivity of the single electron transistor is increased, but the suppression of the tunnel current between the electrodes becomes difficult. Therefore, a design of the readout capacitance which couples trap electrode 103 and island electrode 110 must be implemented considering suppression of the tunnel current between trap electrode 103 and island electrode 110, and securement of high sensitivity of the single electron transistor.

In addition, the single electron transistor is divided into a type of high frequency single electron transistor (RF-SET) which uses a high frequency, and a type of single electron transistor (SET) which does not use a high frequency. In the present invention, a single electron transistor using no high frequency is used.

If island electrode 110 is coupled with superconducting box electrode 106 through a capacitance, a quantum bit state of electron Cooper-pair which is generated in superconducting box electrode 106 and has a very short life time must be observed very quickly before the annihilation of the electron Cooper-pair. Therefore, the readout single electron transistor must be configured with a high frequency single electron transistor. However, a peripheral circuitry for operating the high frequency single electron transistor with high frequency becomes very complex, thereby not preferable.

On the other hand, when island electrode 110 of a single electron transistor is coupled with trap electrode 103 through a capacitance, island electrode 110 of a single electron transistor is coupled with trap electrode 103, which is coupled with superconducting box electrode 106 through the second tunnel barrier 108, through readout capacitance 105, thereby accumulating an excess Cooper-pair in trap electrode 103, a change of electric charge accumulated in trap electrode 103, that is, a change of the number of excess Cooper-pair is read out as a direct current value of the readout single electron transistor. In this case, the readout single electron transistor is not necessary to be configured with a high frequency single electron transistor. That is, since it is not necessary to operate a readout single electron transistor with high frequency, the peripheral circuitry can be simplified.

Therefore, a single electron transistor which has trap electrode 103 coupling with superconducting box electrode 106 through the second tunnel barrier 108 and island electrode 110 coupling with trap electrode 103 through readout capacitance 105 are essential configuration elements for a quantum computing device according to the present invention.

That is, it is configured such that, by applying a bias voltage between counter electrode 104 and trap electrode 103, thereby extracting an excess Cooper-pair existing in superconducting box electrode 106 to trap electrode 103 when the bias is applied, a change of current value flowing in the single electron transistor before and after the extraction of the excess Cooper-pair is measured.

With this configuration, the excess Cooper-pair in superconducting box electrode 106 after quantum computation is accumulated in trap electrode 103, thereby it becomes possible to read out a change of electronic charge accumulated in trap electrode 103, that is, a change of the number of excess Cooper-pair, as a direct current value of the readout single electron transistor. Therefore, since fast readout of a signal is not necessary, use of a high frequency single electron transistor is not needed. Accordingly, since a high frequency control circuit for operating a single electron transistor with high frequency is not necessary, a circuit configuration of the peripheral circuit can be simplified.

In addition, using a single electron transistor as a high sensitive electric charge counter, an observation of the quantum bit state becomes possible with a single trial.

Therefore, the quantum computing device according to the present invention is quite different in the configuration and the effect from a quantum computing device which merely directly couples a quantum box electrode of quantum bit structure with a high frequency single electron transistor.

An operation of the quantum computing device according to the present invention will be explained herein below.

Superconducting box electrode 106 composed of a superconducting film formed on an insulating substrate is coupled with counter electrode 104 composed of a superconducting film by sandwiching a first tunnel barrier 107 with the both.

In addition, a first gate electrode 101 is disposed close to superconducting box electrode 106 through a first gate capacitance 102, and trap electrode 103 is coupled with superconducting box electrode 106 through a second tunnel barrier 108.

A Cooper-pair come into superconducting box electrode 106 through the first tunnel barrier 107 is transformed into two electrons by discharging energy after a time passage, and reaches to trap electrode 103 by tunneling the second tunnel barrier 108. A time corresponding to the life time of the Cooper-pair in this process is called carrier relaxation time. Also, a period of coherent vibration of the Cooper-pair is called coherent vibration period.

A thickness of an insulating film configuring the second tunnel barrier 108 is formed thicker than that of the first tunnel barrier 107, so as to make the carrier relaxation time through the second tunnel barrier 108 longer than the coherent vibration period through the first tunnel barrier 107.

This is for the purpose of making possible to conduct a quantum computation with coherent vibration of Cooper-pair through the first tunnel barrier 107 during a sufficiently long time before the relaxation of the electron takes place through the second tunnel barrier 108.

Then, by controlling a static potential of superconducting box electrode 106 with a gate voltage applied to a first gate electrode 101, a tunneling of Cooper-pair between superconducting box electrode 106 and counter electrode 104 through the first tunnel barrier 107, that is, a transition of quantum bit state can be controlled.

On the other hand, counter electrode 104 is negatively biased, therefore two electrons are extracted by tunneling of two quasi-particles through the second tunnel barrier 108 only when the excess Cooper-pair exists in superconducting box electrode 106.

When counter electrode 104 is negatively biased, since it is not necessary to apply a bias to trap electrode 103, a zero-bias for source electrode 109 and drain electrode 113 of the readout single electron transistor can be maintained during the computation.

In addition, a similar effect can be obtained by applying an equal positive bias to source electrode 109 and drain electrode 113 of the readout single electron transistor, and also by applying positive bias to trap electrode 103 during the computation.

After completing the computation, a current is measured by positively biasing source electrode 109 of the single electron transistor, and by comparing the current with that of before the computation, 0-state and 1-state can be distinguished.

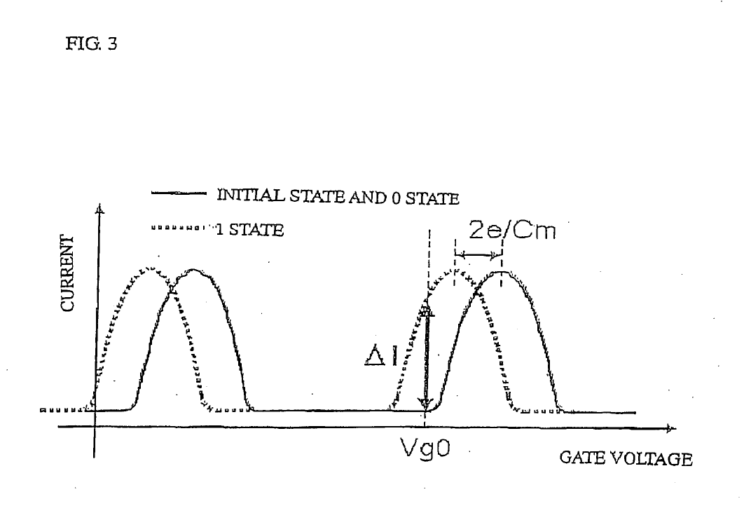

A method for reading out of the quantum bit will be explained referring to FIG. 3.

In FIG. 3, the abscissa is a voltage value applying to the second gate electrode 111 of the readout single electron transistor, and the ordinate is a current value flowing in the readout single electron transistor.

This current is a function periodically vibrating against the gate voltage due to characteristics of the single electron transistor.

If an excess Cooper-pair exists in trap electrode 103, a potential of island electrode 110 of the single electron transistor changes through readout capacitance 105.

As a result, function of the current shifts to the direction of abscissa by 2e/Cm. The e is an elementary charge, and the Cm is a magnitude of readout capacitance 105.

Therefore, in the initial state before the computation, when a voltage applying to the second gate electrode 111 of the single electron transistor is set at, for example as shown in FIG. 3, Vg0, if the state after the computation is “0”, that is, if the excess Cooper-pair does not exist in trap electrode 103, the current remains at zero. However, if the state after the computation is “1”, that is, if the excess Cooper-pair exists in trap electrode 103, the current of ?I is detected.

From the above, the above-described two states can be distinguished.

After completing the reading out, an initialization can be implemented by extracting the accumulated charge in trap electrode 103 by positively biasing counter electrode 104.

As explained in the above, according to the embodiment of the present invention, by accumulating an excess Cooper-pair extracted from superconducting box electrode 106 in trap electrode 103, a change of the charge quantity can be read out as a direct current value of the readout single electron transistor.

Therefore, since a fast readout of signal is not needed, the circuit configuration can be simplified.

In addition, using a single electron transistor as a high sensitive electric charge counter, an observation of the quantum bit state with a single trial becomes possible without averaging the quantity of electric charge.

Next, a fabrication method of the quantum computing device according to the present invention will be explained.

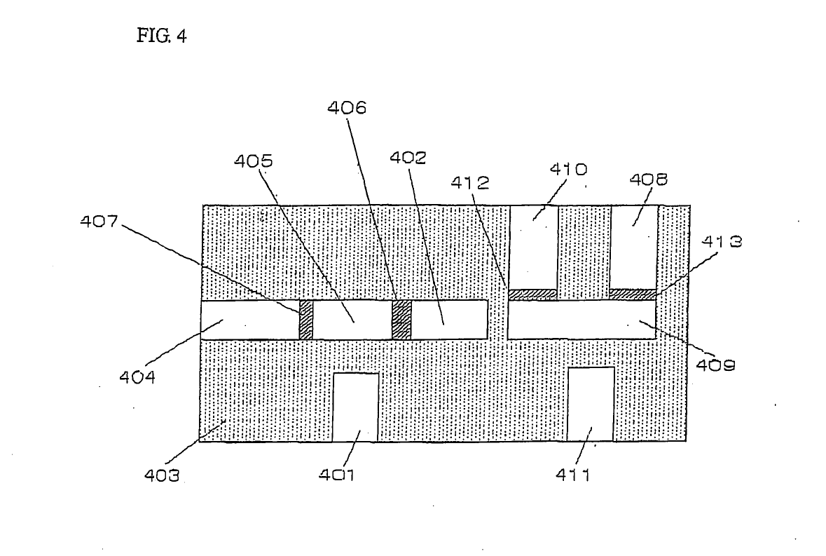

FIG. 4 is a plane view showing a quantum computing device according to one of the embodiment of the present invention.

For insulating substrate 403, for example, a silicon substrate with oxidized surface can be used.

Each electrode of superconducting box electrode 405, counter electrode 404, trap electrode 402, a first gate electrode 401, island electrode 409, drain electrode 410, and source electrode 408 is formed with, for example, Aluminum or Niobium which become to be superconducting state at low temperature.

For the first gate electrode 401 and a second gate electrode 411, a normal conducting noble metal, for example, gold or platinum can also be used as well as the above superconducting materials.

A size of each electrode is typically about 50 nm in width and about 700 nm in length regarding superconducting box electrode 405, trap electrode 402, and island electrode 409.

A first tunnel barrier 407 composed of Aluminum oxide, which is used for a tunnel junction, is formed with processes such that, after forming superconducting box electrode 405 with evaporation, a surface of superconducting box electrode 405 is oxidized by introducing Oxygen into the vacuum chamber, and after that, counter electrode 404 is formed with evaporation so that the counter electrode 404 is slightly overlayed with superconducting box electrode 405.

Next, a second tunnel barrier 406 is formed with processes such that, after evaporation of counter electrode 404, by reintroducing Oxygen into the vacuum chamber, a surface of superconducting box electrode 405 is further oxidized, after that, trap electrode 402 is formed with evaporation so that trap electrode 402 is slightly overlayed with superconducting box electrode 405.

A third tunnel barrier 412 and a fourth tunnel barrier 413 of the readout single electron transistor are formed with a similar manner to the above.

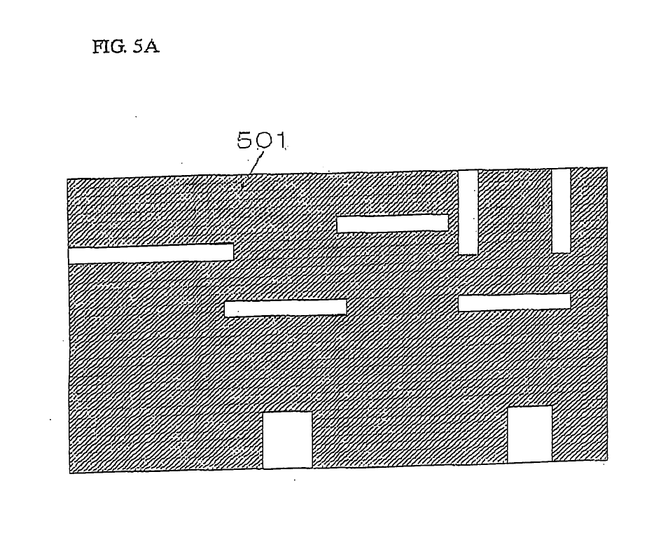

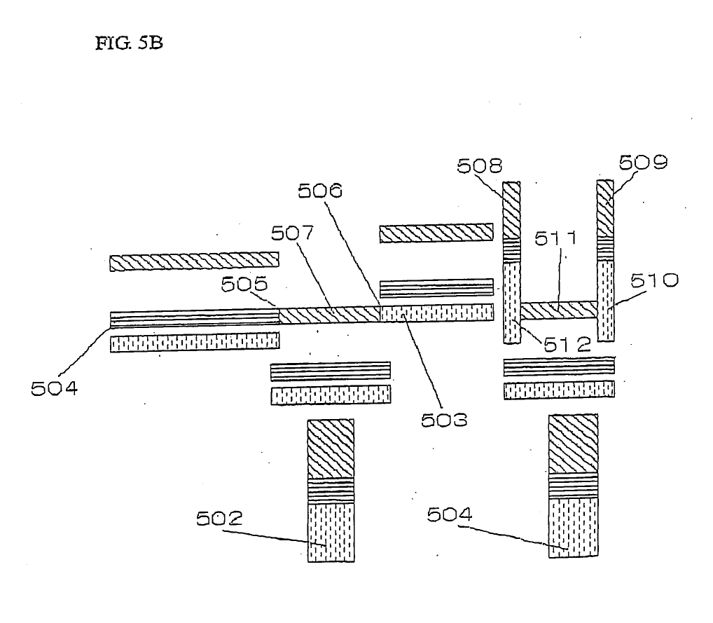

FIG. 5A and FIG. 5B are views showing one of the example of a fabrication process according to one of the embodiment of the present invention.

In FIG. 5A, an example of a mask pattern which is used for forming electrodes is shown. In FIG. 5B, a plan view of the quantum computing device after evaporation process is also shown.

After evaporating Aluminum, typically about 150 nm in thickness, using mask 501 shown in FIG. 5A, as superconducting box electrode 507 and island electrode 511, the surface is oxidized by introducing Oxygen or a mixture gas of 10% Oxygen and 90% Argon into the vacuum chamber of the evaporation apparatus.

When Niobium is used as an electrode material, Aluminum is slightly evaporated in advance on a surface of the Niobium electrode, and after that, oxidation treatment for the Aluminum is conducted.

Next, counter electrode 504, source electrode 508, and drain electrode 509 are evaporated from different angles so as to be slightly overlayed with superconducting box electrode 507 and island electrode 511 at the surfaces.

An Aluminum oxide sandwiched by the overlayed part of the electrode metal forms a tunnel barrier, and resulting in formation of the first tunnel barrier 505, the third tunnel barrier 510, and the fourth tunnel barrier 512.

It is favorable that the second tunnel barrier 506 at trap electrode 503 side has a sufficiently large resistance compared with tunnel barrier 505. Therefore, after evaporating counter electrode 504, Oxygen is reintroduced in the vacuum chamber for further oxidation of the surface of superconducting box electrode 507, after that, an evaporation is conducted to form the second tunnel barrier 506, so as to slightly overlay trap electrode 503 with superconducting box electrode 507.

A thickness of a tunnel barrier is, typically, about 1 nm for the first tunnel barrier 505, the third tunnel barrier 510, and the fourth tunnel barrier 512. On the other hand, it is about 1 nm to 3 nm for the second tunnel barrier 506.

With the above conditions, the coherent vibration period is about 20 psec to 200 psec, typically 100 psec, and the carrier relaxation time is about 1 nsec to 20 nsec, typically 10 nsec.

Through the above processes, the first gate electrode 502 and the second gate electrode 503 are also formed, thereby completing the quantum computing device shown in FIG. 5B.

As described in the above, according to the present invention, a direct current value can be read out with a single trial without averaging information of a quantum bit. Accordingly, configurations of a readout processing circuit and a quantum bit circuit can be simplified.

### POSSIBILITY FOR INDUSTRIAL APPLICATION

A quantum computing device, a readout processing unit of a quantum bit of the quantum computing device, and a method of readout processing of the quantum bit according to the present invention are not limited in the application, and typically, they can be applied to a quantum computer configured with a Josephson coupling system.

While the present invention has been described by associating with some preferred embodiments and examples, it is to be understood that these embodiments and examples are merely for illustrative of the invention by an example, and not restrictive. While it will be obvious to those skilled in the art that various changes and substitutions by equivalent components and techniques are eased upon reading the specification, it is believed obvious that such changes and substitutions fit into the true scope and spirit

What is claimed is:

1. A quantum computing device, comprising:
a quantum bit structure coupling a quantum box electrode and a counter electrode by sandwiching a first tunnel barrier;
a first gate electrode coupling with the quantum box electrode through a static capacitance;
a trap electrode coupling with the quantum box electrode through a second tunnel barrier; and
a single electron transistor,
wherein the single electron transistor, further comprising a source electrode, drain electrode, an island electrode, and a second gate electrode coupling with the island electrode,
wherein the trap electrode and the island electrode of the single electron transistor being coupled through a readout capacitance.

2. A quantum computing device according to claim 1, wherein the quantum box electrode, the counter electrode, and the trap electrode are composed of a superconducting material.

3. A quantum computing device according to claim 1, wherein a carrier relaxation time through the second tunnel barrier is longer than a coherent vibration period through the first tunnel barrier.

4. A quantum computing device according to claim 3, wherein the carrier relaxation time through the second tunnel barrier is between 5 times to 1000 times of the coherent vibration period through the first tunnel bather.

5. A quantum computing device according to claim 1, wherein the first tunnel barrier is consist of a first insulating film and the second tunnel barrier is consist of a second insulating film, wherein a thickness of the second insulating film being thicker than a thickness of the first insulating film.

6. A quantum computing device according to claim 5, wherein the thickness of the second insulating film is between 1 times to 3 times of the thickness of the first insulating film.

7. A quantum computing device according to claim 1, wherein the island electrode is coupled with the source electrode through a third tunnel barrier, and coupled with the drain electrode through a fourth tunnel barrier.

8. A quantum computing device according to claim 1, wherein the quantum computing device is configured such that, by applying a negative bias voltage to the counter electrode, thereby extracting an excess Cooper-pair existing in the superconducting box electrode to the trap electrode when the negative bias is applied and accumulating the excess Cooper-pair in the trap electrode, a change of current value flowing in the single electron transistor before and after the extraction of the excess Cooper-pair is measured.

9. A quantum computing device according to claim 1, wherein the quantum computing device is configured such that, by applying a positive bias voltage to the trap electrode, thereby extracting an excess Cooper-pair existing in the superconducting box electrode to the trap electrode when the positive bias is applied and accumulating the excess Cooper-pair in the trap electrode, a change of current value flowing in the single electron transistor before and after the extraction of the excess Cooper-pair is measured.

10. A quantum bit readout processing unit of a quantum computing device, comprising:
a single electron transistor comprising a source electrode, a drain electrode, an island electrode, and a gate electrode coupling with the island electrode through a gate capacitance; and
a trap electrode coupling with the island electrode through a readout capacitance as well as coupling with a quantum box electrode of the quantum computing device through a tunnel barrier,
wherein the quantum bit readout processing unit being configured so that a change of current value flowing in the single electron transistor is measured before and after extraction of an excess Cooper-pair existing in the quantum box electrode to the trap electrode when a bias voltage is applied to the quantum computing device.

11. A quantum bit readout processing unit of a quantum computing device according to claim 10, wherein the quantum computing device, comprising:
a quantum bit structure coupling the quantum box electrode and a counter electrode through a first tunnel barrier;
a gate electrode coupling with the quantum box electrode through a static capacitance; and
the trap electrode coupling with the quantum box electrode through a second tunnel barrier.

12. A quantum bit readout processing unit of a quantum computing device according to claim 11, wherein the bias voltage to be applied to the quantum computing device is a negatively biased voltage which is applied to the counter electrode.

13. A quantum bit readout processing unit of a quantum computing device according to claim 11, wherein the bias voltage applied to the quantum computing device is a positively biased voltage applied to the trap electrode.

14. A quantum bit readout processing unit of a quantum computing device according to claim 11, wherein the quantum box electrode, the counter electrode, and the trap electrode are composed of a superconducting material.

15. A quantum bit readout processing unit of a quantum computing device according to claim 11, wherein a carrier relaxation time through the second tunnel barrier is longer than a coherent vibration period through the first tunnel barrier.

16. A quantum bit readout processing unit of a quantum computing device according to claim 15, wherein the carrier relaxation time through the second tunnel barrier is between 5 times to 1000 times of the coherent vibration period through the first tunnel barrier.

17. A quantum bit readout processing unit of a quantum computing device according to claim 11, wherein the first tunnel barrier is consist of a first insulating film and the second tunnel barrier is consist of a second insulating film, wherein a thickness of the second insulating film being thicker than a thickness of the first insulating film.

18. A quantum bit readout processing unit of a quantum computing device according to claim 17, wherein the thickness of the second insulating film is between 1 times to 3 times of the thickness of the first insulating film.

19. A quantum bit readout processing unit of a quantum computing device according to claim 10, wherein the island electrode is coupled with the source electrode through a third tunnel barrier, and coupled with the drain electrode through a fourth tunnel barrier.

20. A quantum bit readout method of a quantum computing device, comprising steps of:
extracting an excess Cooper-pair existing in a quantum box electrode to a trap electrode of a quantum computing device when a bias voltage is applied to the quantum computing device; and
measuring a change of a current value flowing in a single electron transistor, which includes an island electrode coupling with the trap electrode through a readout capacitance, before and after the extracting of the excess Cooper-pair.

21. A quantum bit readout method of a quantum computing device according to claim 20, wherein the bias voltage applied to the quantum computing device is a negatively biased voltage applied to a counter electrode of the quantum computing device.

22. A quantum bit readout method of a quantum computing device according to claim 20, wherein the bias voltage to be applied to the quantum computing device is a positively biased voltage which is applied to the trap electrode.
